(19) United States
(12) Patent Application Publication
(10) Pub. No.: US 2007/0020810 A1
(43) Pub. Date: Jan. 25, 2007

(54) Thermoplastic/thermoset composition material and method of attaching a wafer to a substrate

(75) Inventors: Brian Eisenach, Alpharetta, GA (US); Michael A. Previti, Alpharetta, GA (US); Mark Wilson, Cumming, GA (US); Avin Dhoble, Alpharetta, GA (US)

Correspondence Address: LOWRIE, LANDO & ANASTASI, RIVERFRONT OFFICE, ONE MAIN STREET, ELEVENTH FLOOR, CAMBRIDGE, MA, 02142, US

(73) Assignee: Cookson Singapore Pte Ltd., Singapore (SG)

(21) Appl. No.: 11/455,226

(22) Filed: Jun. 16, 2006

Related U.S. Application Data
(60) Provisional application No. 60/691,919, filed on Jun. 17, 2005.

(51) Int. Cl. H01L 21/00; H01L 23/48; H01L 29/40; H01L 23/52; B32B 33/00; B32B 9/00

(52) U.S. Cl. 438/118; 428/40.1

(57) ABSTRACT

A process for mounting a wafer on a substrate includes applying a pre-applied die attach on a backside of the wafer with a composition having a thermoplastic portion and a thermoset portion. The composition has a predetermined cure temperature. The process further includes heating the wafer to a temperature sufficient to remove solvents from the thermoplastic portion of the composition below the cure temperature, mounting the wafer on the substrate, and heating the wafer and the substrate to a temperature above the cure temperature to cure the thermoset portion of the pre-applied die attach composition. A composition for performing the process is further disclosed.

### RELATED APPLICATION

This application claims priority under 35 U.S.C. § 119(e) to U.S. Provisional Application Ser. No. 60/691,919, entitled “THERMOPLASTIC/THERMOSET COMPOSITION MATERIAL AND METHOD OF ATTACHING A DIE TO A SUBSTRATE (PRE-APPLIED DIE ATTACH OR WAFER APPLIED DIE ATTACH)” filed on Jun. 17, 2005, which is herein incorporated by reference in its entirety.

### BACKGROUND OF THE INVENTION

1. Field of the Invention

This invention relates generally to thermoplastic and thermoset materials and methods of attaching an electronic component, such as a silicon wafer or die, to a substrate, such as a printed circuit (or wire) board (“PCB” or “PWB”), and more particularly, to a novel application of coating a thermoplastic/thermoset composition material to a wafer and mounting a die of the wafer to the substrate using fewer process steps and less attachment material.

2. Discussion of Related Art

Materials and processes used to attach or mount an electrical component, such as a silicon wafer or “die,” on a substrate, such as a PCB, are well known in the art of wafer and packaging assembly fabrication. One such method is illustrated in FIG. 1. As shown in step 10, a larger silicon wafer is processed by many processing steps, including, but not limited to, building layers on a silicon blank, etching circuitry into the wafer by means of applying chemicals on the wafer to create electrical traces, and backgrinding the wafer to finish or polish the wafer. It should be understood by those skilled in the art of wafer fabrication that the description of processing the wafer is exemplary, and that many more or fewer steps may be included in processing the wafer.

A protective coating of a selected thermoplastic material is then applied to the backside of the wafer by a spin-coat, spray on, or stencil print process. This step is indicated at 12 in FIG. 1. Typically, the material chosen is a thermoplastic urethane, which may be employed, in most applications, on dies sized 1 mm² or smaller. Thermoplastic materials used in applications having larger dies (i.e., greater than 1 mm²) are susceptible to “die shift” at elevated temperatures since the thermoplastic material lacks sufficient tack to temporarily secure the die to the substrate. Such thermoplastic materials are mixed with solvents to increase the wettability of the coating material.

Solvents in the coating are removed by heating the wafer as illustrated by step 14 in FIG. 1. This step may be performed by placing the wafer in a reflow oven, such an oven sold by Speedline Technologies, Inc. under the brand name Electrovert. Alternatively, for thermosetting or reactive materials, a standard convection oven may be utilized. The solvents used to wet the thermoplastic material evaporate at approximately 100° C. Such solvents may include ketones, alcohols, acetates, glycol ethers, and glycols, for example.

Step 16 of FIG. 1 depicts the application of tape (known as “Nitto” tape in the art) on the backside of the wafer. Such tape may be purchased from Nitto Denko of Osaka, Japan. The tape protects the wafer when the wafer is singulated or cut into several smaller wafers or “dies.”

Next, the coating may be removed, depending on the wafer fabricator's specifications. This is shown in FIG. 1 by step 18. In most instances, however, the protective coating is left on the backside of the wafer to further protect the wafer during subsequent processing.

Step 20 shows the step of coating the topside of the wafer with another protective coating.

The next step of the process illustrated in FIG. 1, indicated by step 22, is to singulate the larger wafer into individual wafers or dies by laser cutting, for example. This step may alternatively be performed by the package assembly fabricator. Subject to the foregoing singulating step 22, all of the foregoing steps (i.e., 10-20) are performed by the wafer fabricator.

The dies are then removed from the tape and placed in one of several temporary storage configurations, either in tape or on a tape and reel or in waffle packs.

The next stage of the process shown in FIG. 1, which is performed by the package assembly fabricator, is to dispense die attach material on the substrate (e.g., the PCB) at step 24. Alternatively, and not preferably, the die attach material may be applied to the die. Typical die attach materials include, and are not limited to, thermoset epoxies and cynate esters, which, for example, may be purchased from Ablestick of Rancho Dominguez, Calif. The die attach material is provided to secure the die in place until the die is mechanically and electrically connected to the substrate. Die attach materials provide a stronger bond between the die and the substrate thereby preventing the die shift phenomenon described above when only a thermoplastic material is used. The die attach material may be applied to the substrate (or die, as the case may be) by any of the well-known dispensing apparatus, such as dispensers sold under the brand name Camalot by Speedline Technologies, Inc. of Franklin, Mass.

The next step 26 of the process involves mounting the die on the substrate on the area having the die attach material. This step is performed by a pick and place machine, such as those sold by Assembléon of Eindhoven, Netherlands. Specifically, the die is manipulated by the pick and place machine to position the die on the substrate with the backside adjacent to the substrate. The die is maintained in position until it is permanently secured to the substrate in the manner set forth below.

The next step in the process, identified by step 28 in FIG. 1, is to heat the substrate to cure the die attach material. Since the die attach material is a thermoset material, the polymer matrix of the material cross-links to create a secure bond. This bond is not meant to permanently attach the die to the substrate, but is sufficient to prevent die shift, i.e., the slight (or not so slight) movement of the die relative to the substrate. As can be appreciated by those skilled in the art of surface mount applications, the precise nature of PCB fabrication requires the die to be accurately placed on the substrate prior to the permanent affixation of the die on the substrate. The die and the substrate may be heated to a temperature between 150° C. and 225° C., depending on the particular die attach material and sensitivity of the dies and substrate being processed. This step 26 of the process may be performed by a conventional reflow oven, such as an oven offered by Speedline Technologies, Inc. under the brand name Electrovert.

For the limited purpose of this disclosure, the last step of the process is to wire bond the die to the substrate, which is indicated by step 30 in FIG. 1. As mentioned briefly above, step 30 involves attaching a wire, fabricated from gold or copper, or some other suitable conductive metal or alloy, to the die and the substrate. This wire bond provides both mechanical attachment of and electrical communication between the die and the substrate. Step 30 may be achieved by a wire bonding machine offered by Kulicke Soffa of Willow Grove, Pa.

As can be appreciated by those skilled in the art, this process involves many costly steps, and, as discussed above, is limited to small dies if a thermoplastic material is used to avoid having to disperse a thermoset material to attach the die to the substrate. There is presently a need for a process that reduces the number of process steps while enabling the attachment of larger dies to the substrate. Also, it should be appreciated that the process may involve many other process steps not specifically disclosed herein.

### SUMMARY OF THE INVENTION

One aspect of embodiments of the invention is directed to a process for mounting a wafer on a substrate. In one embodiment, the process comprises: applying a pre-applied die attach on a backside of the wafer with a composition having a thermoplastic portion and a thermoset portion, the composition having a cure temperature; heating the wafer to a temperature sufficient to remove solvents from the thermoplastic portion of the composition below the cure temperature; mounting the wafer on the substrate; and heating the wafer and the substrate to a temperature above the cure temperature to cure the thermoset portion of the pre-applied die attach composition.

Embodiments of the process may further comprise one or more of the following: processing the wafer prior to applying the pre-applied die attach composition to the backside of the wafer; applying tape to the backside of the wafer; coating a topside of the wafer with a protective coating; singulating the wafer to an electrical die component prior to mounting the wafer on the substrate; and/or wire bonding the die component to the substrate. The thermoplastic portion may comprise between 0% and 95% by weight of the composition and the thermoset portion may comprise between 5% and 100% by weight of the composition. The thermoplastic portion may comprise between 15% and 45% by weight of the composition and the thermoset portion may comprise between 55% and 85% by weight of the composition. The thermoplastic portion may comprise a solvent capable of evaporating at a temperature below 120° C. The thermoset portion may be cured at a temperature above 150° C. In one embodiment, the step of applying a pre-applied die attach on a backside of the wafer may comprise one of a spin coating method, a spraying method and a stenciling method.

Another embodiment of the invention is directed to a composition used in a process of attaching a wafer to a substrate. In one embodiment, the composition comprises a thermoplastic portion and a thermoset portion. The thermoplastic portion comprises between 0% and 95% by weight of the composition, with the thermoplastic portion comprising a solvent capable of evaporating at a temperature below 120° C. The thermoset portion comprises between 5% and 100% by weight of the composition, with the thermoset portion being cured at a temperature above 150° C.

Embodiments of the composition may include thermoplastic portion comprising between 15% and 45% by weight of the composition and the thermoset portion comprises between 55% and 85% by weight of the composition. The thermoplastic portion may be selected from a group consisting of phenoxy resins, acrylic resins, polyethylene, styrene, nylon, liquid crystal polymers and urethane resins. The thermoset portion may be selected from a group consisting of polybenzoxazine cured epoxy, phenol cured epoxy, latent amine cured epoxy and aromatic amine cured epoxy. In a certain embodiment, the solvent of the thermoplastic portion evaporates at approximately 100° C. In another embodiment, thermoset portion is cured at a temperature between 200° C. and 400° C.

A further aspect of the invention is directed to a process for mounting a wafer on a substrate. In one embodiment, the process comprises: processing the wafer; applying a pre-applied die attach on a backside of the wafer with a composition having one of a thermoplastic portion and a thermoset portion, the composition having a cure temperature; applying tape to the backside of the wafer; singulating the wafer to an electrical die component; mounting the die component on the substrate; heating the die component and the substrate to a temperature above the cure temperature to cure the thermoset portion of the pre-applied die attach composition; and wire bonding the die component to the substrate. In an embodiment, the process further comprises heating the wafer to a temperature sufficient to remove solvents from the thermoplastic portion of the composition below the cure temperature.

### DESCRIPTION OF THE DRAWINGS

For a better understanding of the present invention, reference is made to the drawing figures which are incorporated herein by reference and in which:

FIG. 1 is a view of a prior art process of attaching a die to a substrate; and

FIG. 2 is a view of a process of an embodiment of the present invention for attaching a die to a substrate.

### DETAILED DESCRIPTION OF THE INVENTION

This invention is not limited in its application to the details of construction and the arrangement of components set forth in the following description or illustrated in the drawings. The invention is capable of other embodiments and of being practiced or of being carried out in various ways. Also, the phraseology and terminology used herein is for the purpose of description and should not be regarded as limiting. The use of “including,” “comprising,” or “having,” “containing,” “involving,” and variations thereof herein, is meant to encompass the items listed thereafter and equivalents thereof as well as additional items.

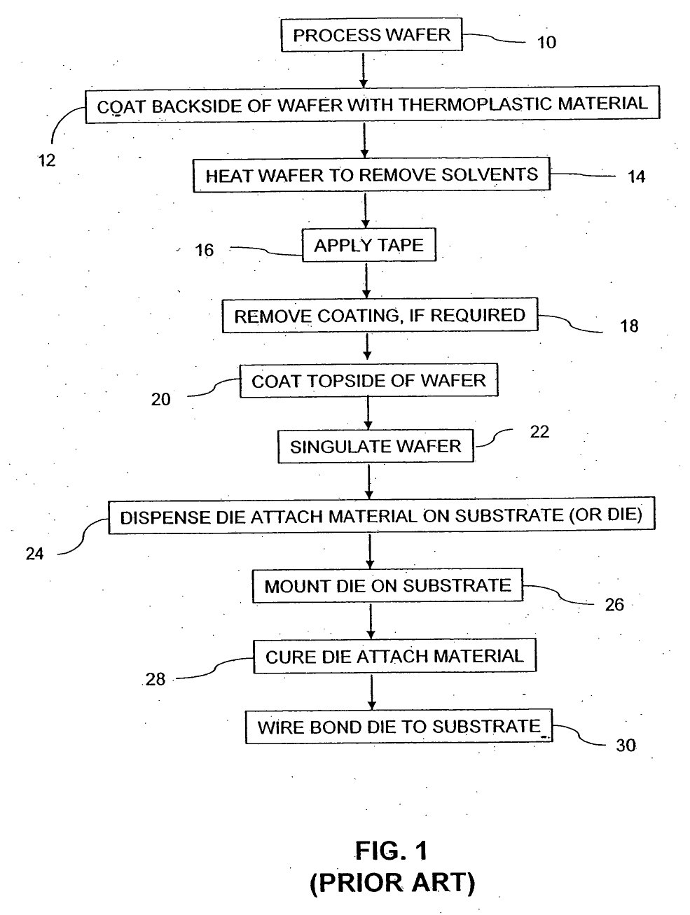

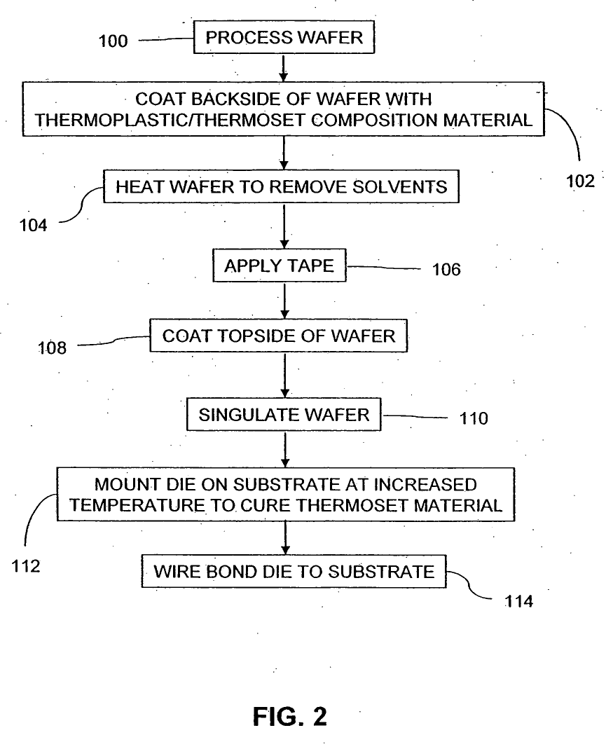

Referring to FIG. 2, there is disclosed a process of the present invention for attaching a die to a substrate using a thermoplastic/thermoset composite material of embodiments of the invention. As shown in step 100, the wafer is processed in an identical manner as described by step 10 of FIG. 1.

Next, the backside of the wafer is coated by using a spin-coat, spray on, or stencil print process with a thermoplastic/thermoset composition material of an embodiment of the invention. This step is illustrated by step 102 of FIG. 2. As described above, standard thermoplastic materials used in prior art processes do not provide the sufficient tack required to secure larger dies to the substrate, thus the requirement of dispensing die attach material (see step 24 of FIG. 1) at a later process step.

The coating material of an embodiment of the present invention includes a thermoplastic portion, which comprises approximately 0% to 100% by weight of the overall composition, and a thermoset portion, which comprises approximately 0% to 100% by weight of the overall composition. Preferably, the thermoplastic portion comprises between 0% and 95% by weight of the overall composition and the thermoset portion comprises between 5% and 100% by weight of the overall composition. Most preferably, the thermoplastic portion comprises approximately 15% to 45% by weight of the overall composition and the thermoset portion comprises approximately 55% to 85% by weight, depending on the particular application, e.g., wire bonding. Suitable thermoplastic materials include, but are not limited to, phenoxy resins, acrylic resins, polyethylene, styrene, nylon, liquid crystal polymers and urethane resins. Such resins are available from InChem Resins of Rock Hill, S.C., or DuPont Engineering Polymers, E. I. DuPont de Nemours & Co. of Wilmington, Del. Suitable thermoset materials include, and are not limited to, polybenzoxazine cured epoxy, phenol cured epoxy, latent amine cured epoxy, and aromatic amine cured epoxy, and are available from suitable providers. The thermoplastic and thermoset materials are selected based on the particular application process requirements.

After deposition, step 104 illustrates the heating of the wafer to a temperature of approximately 100° C. to remove (evaporate) the solvents contained in the coating. The particular temperature chosen at this step 104 depends on the particular thermoplastic material, the reactivity of the thermosetting resin and solvent used in the process. Since the thermoset portion of the thermoplastic/thermoset composition is highly latent below its cure temperature, e.g., approximately 200° C., it does not cross-link during step 104 of the process. The advantage of this aspect of the invention will be apparent below. Alternatively, a true b-stageable thermoset material may be utilized to form the film. In this example, a small amount of conversion occurs during the pre-heating step.

Tape is applied to the backside of the wafer in step 106 in the same manner as step 16 in FIG. 1. Similarly, the topside of the wafer is coated in step 108 in a similar manner as step 18 in FIG. 1. Next, the wafer is singulated in step 110. Steps 100-110, as described above, are typically performed by the wafer fabricator, the only exception being the singulating step (i.e., step 110), which may be performed by the packaging assembly fabricator.

Because of the novel thermoplastic/thermoset composition material of an embodiment of the invention, there is no need to dispense die attach material as required with the process illustrated in FIG. 1. The die can proceed directly to being mounted on the substrate.

Specifically, and with reference to step 112 in FIG. 2, when the die is placed on the substrate by the pick and place machine, step 112 is performed at an elevated temperature of approximately 200° C. to 400° C. to cure the thermoset portion of the composition. This results in a secure attachment of the die to the substrate suitable to prevent die shift, the secure attachment being caused by the cross-linking of the polymer matrix of the thermoset portion of the composition. Stated another way, the cross-linking of the polymer matrix is caused by a chemical change of the composition to firmly affix the die to the substrate.

The last step of the process illustrated in FIG. 2, step 114, involves wire bonding the die and the substrate with a wire fabricated from gold, copper or other suitable metal or alloy. This step 114 is identical to step 30 shown in FIG. 1. As discussed above, other processing steps may be included.

There are several advantages associated with the process shown and described in FIG. 2. Firstly, the step of dispensing the die attach material on the substrate (i.e., step 24 of FIG. 1) is eliminated. Secondly, there is no tendency for film bleed caused by the die attach material. Thirdly, there is no outgas to contaminate the wire bond pads of the substrate that may be caused by the die attach material. And finally, unlike typical die attach material, the thermoplastic portion of the thermoplastic/thermoset composition coating is re-workable, thereby enabling the packaging assembly fabricator to re-work a defective substrate even though the thermoset portion is cured. Thus, when a defect is detected, the assembly may be re-worked, rather than throwing the assembled substrate away.

Thus, it should be observed that the method and composition of the present invention enables the wafer fabricator and the packaging assembly fabricator to reduce the number of steps of the fabrication process as well as reduce the amount of materials used in the process. Specifically, the wafer fabricator is not faced with the decision of having to remove the backside of the coating. Also, and more pointedly, the packaging assembly fabricator is not required to dispense die attach material. Not only are the material costs to the packaging assembler greatly reduced, the need for a dedicated dispensing apparatus is eliminated. Also, the thermoplastic/thermoset material can also be quickly cured by a pick and place machine adapted to heat the die and the substrate. Pick and place machines suitable for this assembly method are also available from Siemens, Philips, Panasonic and Fuji, for example.

The function and advantages of these and other embodiments of the invention can be further understood from the examples provided below. The following examples illustrate the benefits and/or advantages of the one or more systems and techniques of the invention but do not exemplify the full scope of the invention.

### EXAMPLES

### Example 1

| | | Percent of Total |
|---|---|---|
| | | Composition |
| Ingredient | Manufacturer | (By Weight) |
| Tactix 742 | Huntsman Chemical, | 0.0330 |
| | The Woodlands, TX | |
| Araldite MY 0510 | Huntsman Chemical, | 0.0110 |
| | The Woodlands, TX | |
| Type B-m | Shikoku, Kagawa, JP | 0.0489 |
| Polybenzoxazine | | |
| Ethyl Acetate | Eastman Chemical, | 0.2567 |
| | Kingsport, TN | |
| Radel R 5800 FP | Solvay Advanced | 0.0929 |
| | Polymers, LLC, | |
| | Alpharetta, GA | |
| Silver Flake SA-00201 | Metalor Technologies, | 0.5575 |
| | Attleboro, MA | |

### Example 2

| | | Percent of Total |
|---|---|---|
| | | Composition |
| Ingredient | Manufacturer | (By Weight) |
| EOCN 1020-55 MB | Nippon Kayaku Co., Ltd., | 0.0603 |
| | Tokyo, JP | |
| Carbitol | Eastman Chemical, | 0.1374 |
| | Kingsport, TN | |
| Tamanol 758 | Arakawa Chemical | 0.0377 |
| | Industries, Ltd., Osaka JP | |
| MEH-7500 | Meiwa Plastic Industries, | 0.0223 |
| | Ltd., Yamaguci Pref., JP | |
| Tactix 742 | Huntsman Chemical, | 0.0172 |
| | The Woodlands, TX | |
| Epiclon 830 LVP | Dianippon Ink and | 0.0273 |
| | Chemical, Chiba, JP | |
| TPP-k | Hokko Chemical Industry | 0.0016 |
| | Co., Ltd., Tokyo, JP | |
| Cyclohexanone | Aldrich, Atlanta, GA | 0.0046 |
| Silane A-187 | GE Advanced Materials, | 0.0027 |
| | Wilton, CT | |
| RA-0081 | Metalor Technologies, | 0.6200 |
| | Attleboro, MA | |
| SFQ-ED Powder | Ferro Electronics | 0.0689 |
| | Material Systems, So. | |
| | Plainfield, NJ | |

With both examples, the die was securely attached to the substrate to prevent die shift. Thus, the compositions used in both examples were capable of performing methods of embodiments of the invention. With Example 1, the thermoplastic portion is the Radel R 5800 FP material. The remaining components (resins) are the epoxy and hardener (thermoset portion) that cure after the removal of the solvent.

Having thus described several aspects of at least one embodiment of this invention, it is to be appreciated various alterations, modifications, and improvements will readily occur to those skilled in the art. Such alterations, modifications, and improvements are intended to be part of this disclosure, and are intended to be within the spirit and scope of the invention. Accordingly, the foregoing description and drawings are by way of example only.

What is claimed is:

1. A process for mounting a wafer on a substrate, the process comprising:
applying a pre-applied die attach on a backside of the wafer with a composition having a thermoplastic portion and a thermoset portion, the composition having a cure temperature;
heating the wafer to a temperature sufficient to remove solvents from the thermoplastic portion of the composition below the cure temperature;
mounting the wafer on the substrate; and
heating the wafer and the substrate to a temperature above the cure temperature to cure the thermoset portion of the pre-applied die attach composition.

2. The process of claim 1, further comprising processing the wafer prior to applying the pre-applied die attach composition to the backside of the wafer.

3. The process of claim 1, further comprising applying tape to the backside of the wafer.

4. The process of claim 3, further comprising coating a topside of the wafer with a protective coating.

5. The process of claim 4, further comprising singulating the wafer to an electrical die component prior to mounting the wafer on the substrate.

6. The process of claim 5, further comprising wire bonding the die component to the substrate.

7. The process of claim 1, wherein the thermoplastic portion comprises between 0% and 95% by weight of the composition and the thermoset portion comprises between 5% and 100% by weight of the composition.

8. The process of claim 7, wherein the thermoplastic portion comprises between 15% and 45% by weight of the composition and the thermoset portion comprises between 55% and 85% by weight of the composition.

9. The process of claim 1, wherein the thermoplastic portion comprises a solvent capable of evaporating at a temperature below 120° C.

10. The process of claim 1, wherein the thermoset portion is cured at a temperature above 150° C.

11. The process of claim 1, wherein applying a pre-applied die attach on a backside of the wafer comprises one of a spin coating method, a spraying method and a stenciling method.

12. A composition used in a process of attaching a wafer to a substrate, the composition comprising:
a thermoplastic portion comprising between 0% and 95% by weight of the composition, the thermoplastic portion comprising a solvent capable of evaporating at a temperature below 120° C.; and
a thermoset portion comprising between 5% and 100% by weight of the composition, the thermoset portion being cured at a temperature above 150° C.

13. The composition of claim 12, wherein the thermoplastic portion comprises between 15% and 45% by weight of the composition and the thermoset portion comprises between 55% and 85% by weight of the composition.

14. The composition of claim 12, wherein the thermoplastic portion is selected from a group consisting of phenoxy resins, acrylic resins, polyethylene, styrene, nylon, liquid crystal polymers and urethane resins.

15. The composition of claim 12, wherein the thrermoset portion is selected from a group consisting of polybenzoxazine cured epoxy, phenol cured epoxy, latent amine cured epoxy and aromatic amine cured epoxy.

16. The composition of claim 12, wherein the solvent of the thermoplastic portion evaporates at approximately 100° C.

17. The composition of claim 12, wherein the thermoset portion is cured at a temperature between 200° C. and 400° C.

18. A process for mounting a wafer on a substrate, the process comprising:
processing the wafer;
applying a pre-applied die attach on a backside of the wafer with a composition having one of a thermoplastic portion and a thermoset portion, the composition having a cure temperature;
applying tape to the backside of the wafer;
singulating the wafer to an electrical die component;
mounting the die component on the substrate;
heating the die component and the substrate to a temperature above the cure temperature to cure the thermoset portion of the pre-applied die attach composition; and
wire bonding the die component to the substrate.

19. The process of claim 18, further comprising heating the wafer to a temperature sufficient to remove solvents from the thermoplastic portion of the composition below the cure temperature.
